(19) United States
(12) Patent Application Publication
(10) Pub. No.: US 2007/0135550 A1
(43) Pub. Date: Jun. 14, 2007

(54) Negative thermal expansion material filler for low CTE composites

(76) Inventors: Nirupama Chakrapani, Chandler, AZ (US); James Matayabas, Chandler, AZ (US); Paul A. Koning, Chandler, AZ (US)

Correspondence Address: INTEL CORPORATION;c/o INTELLEVATE, LLC, P.O. BOX 52050, MINNEAPOLIS, MN, 55402, US

(21) Appl. No.: 11/304,013

(22) Filed: Dec. 14, 2005

(51) Int. Cl. H01L 21/56; C09D 5/08; C08K 3/22

(52) U.S. Cl. 524/406; 264/272.17; 524/413

(57) ABSTRACT

The present invention relates to a filler featuring a negative coefficient of thermal expansion and a bi-modal size distribution of filler particles. In an embodiment, the filler has micron and nanometer size filler particles. The present invention also relates to a composite having a polymer and a filler with nanometer size filler particles. Additionally, the present invention discloses a method of forming an electronic package with a composite having a polymer and a filler with nanometer size filler particles.

### BACKGROUND

1. Field

The present invention relates to the application of materials with a negative coefficient of thermal expansion as fillers for composites used in semiconductor packaging.

2. Description of Related Art

Currently, mold compounds, under-fills, encapsulants, thermoset materials, and other epoxy polymers are used for various applications for semiconductor packaging. Often, these materials have mismatched coefficients of thermal expansion (CTE) with the other materials in the semiconductor package which can cause thermal, mechanical, or other functional problems upon concurrent heating within a semiconductor package.

Silica has been identified and used to remedy detrimental effects associated with materials with mismatched coefficients of thermal expansion. According to certain applications, silica's property of relative low coefficient of thermal expansion qualifies it to be used as a filler material to decrease the CTE of epoxy composites. A relative high loading of silica may be required to effectively lower the CTE of the epoxy composite. However, a high filler loading increases the viscosity of epoxy composites which may have a substantial effect on the rheological properties of the composite in the semiconductor package.

### BRIEF DESCRIPTION OF THE DRAWINGS

FIG. 1A is an illustration of a composite having an uni-modal size distribution of filler particles according to an embodiment of the present invention.

FIG. 1B is an illustration of a composite having a bi-modal size distribution of filler particles according to an embodiment of the present invention.

FIG. 2 is an illustration of an electronic package having a substrate, thermal interface material, and mold compound composite featuring a bi-modal size distribution of filler particles according to an embodiment of the present invention.

FIG. 3A and 3B is an illustration of a composite filled having negative coefficient of thermal expansion, nanometer size filler particles; wherein, the composite expands but the nanometer size filler particles contract upon heating which leads to an overall lower expansion of the composite according to an embodiment of the present invention.

FIG. 4 is a flowchart of a process of manufacturing a mold compound including a bi-modal size distribution of filler particles according to an embodiment of the present invention.

FIG. 5A-5D is an illustration of a process of manufacturing an electronic package having a bi-modal size distribution of filler particles according to an embodiment of the present invention.

### DETAILED DESCRIPTION OF THE PRESENT INVENTION

The present invention includes a composite including a polymer and nanometer size, negative coefficient of thermal expansion (NTE) filler particles. The application of nanometer size NTE filler particles may decrease the loading criteria of fillers in thermoset composites. In other embodiments, the present invention includes a composite including a polymer and a bi-modal size distribution of NTE filler particles. The application of bi-modal size distribution of NTE filler particles may decrease the loading criteria in thermoset composites by accomplishing greater packing as smaller filler particles fill intersticial sites created by bigger filler particles. In yet another embodiment, a composite including a polymer and hafnium tungstate fillers may be used to decrease the coefficient of thermal expansion (CTE) for semiconductor packaging applications.

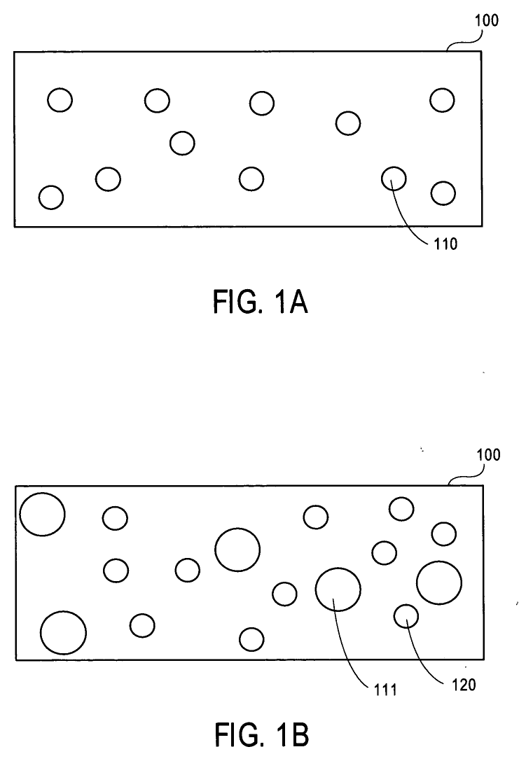

FIG. 1A is an illustration of a composite 100 having a polymer and NTE filler particles 110 disposed within according to an embodiment of the present invention. In an embodiment as illustrated in FIG. 1A, composite 100 includes a uni-modal distribution of filler particles. In an embodiment, composite 100 includes a uni-modal distribution of nanometer size filler particles. NTE filler particles 110 may be dispersed throughout composite 100 or may be concentrated in areas within composite 100. In an embodiment as illustrated in FIG. 1A, NTE fillers 110 are dispersed throughout composite 100. In an embodiment of the present invention, the loading of NTE filler particles 110 includes less than 35% weight fraction of composite 100, which is far less than the 69% theoretical limit for random packing of fillers in solids. In an embodiment as illustrated in FIG. 1A, composite 100 includes a 30% weight fraction of NTE filler 110.

In an embodiment as illustrated in FIG. 1B, composite 100 includes a bi-modal size distribution of filler particles. In an embodiment as illustrated in FIG. 1B, the bi-modal size distribution of NTE filler particles include micron size filler particles 111 and nanometer size filler particles 120. In an embodiment, nanometer size filler particles may range from 1×10⁻⁹ m to 1×10⁻⁷ m and micron size filler particles may range from 1×10⁻⁶ m to 1×10⁻⁴ m. In an embodiment, nanometer size filler particles 120 may occupy the intersticial space between bigger micron size filler particles 120. In an embodiment, a bi-modal size distribution of filler particles leads to better packing within composite 100. In an embodiment, a bi-modal distribution of micron size filler particles 111 and nanometer size filler particles 120 may exhibit greater filler properties in composite 100 than an uni-modal distribution of filler size particles within composite 100. In an embodiment, a 10% loading of micron and nanometer size filler particles within a composite may achieve the same properties as a 40% loading of mainly micron size filler particles within the composite.

In an embodiment, composite 100 includes a polymer such as a thermoset or thermoplastic. Thermoset formulations such as an epoxy, BMI, thermosetting urethane, cyanourate ester, silicone, or combination thereof may be used in composite 100 for semiconductor packaging applications. Composite 100 may also include a thermoplastic formulation such as a polyimide, liquid crystalline polymer, solid or liquid resin.

NTE filler particles 110 may include any material suitable to decrease the thermal expansion when added to composite 100. In an embodiment, NTE filler particles 110 may be selected from zirconium tungstate, hafnium tungstate, and hafnium molybdinate. NTE filler particles 110 may include micron, nanometer, or a bi-modal size distribution of hafnium tungstate filler particles. In an embodiment, NTE filler particles 110 include nanometer size hafnium tungstate filler particles. NTE filler particles 110 may include micron, nanometer, or a bi-modal size distribution of metal cyanide filler particles. In an embodiment, NTE filler particles 110 further include NTE, metal cyanide filler particles with Prussia blue crystalline structures. In other embodiments, composite 100 includes a combination of different NTE filler particles. In an embodiment, both zirconium tungstate and hafnium tungstate are incorporated in composite 100 to decrease the overall thermal expansion of composite 100.

In an embodiment, the coefficient of thermal expansion of composite 100 may be determined when nanometer size fillers are incorporated in composite 100 by a modified rule of mixtures:
α_{composite}=α_{filler}*V_{filler}+αₘₐₜᵣᵢₓ*Vₘₐₜᵣᵢₓ+βᵢ(3V_{filler}/r)
Where r is the average particle radius, βᵢ is the product of αᵢ (CTE of the interface polymer) and tᵢ (thickness of the interface layer), and V is the volume of the filler.

The composite of the present invention may be used in semiconductor packaging for flip-chip, wire bond, MEMS and other type packages. The composite may be used as an underfill, die-attach, mold compound, encapsulant, or sealant. The low CTE composite of the present invention may be used as a mold compound in a flip-chip semiconductor package.

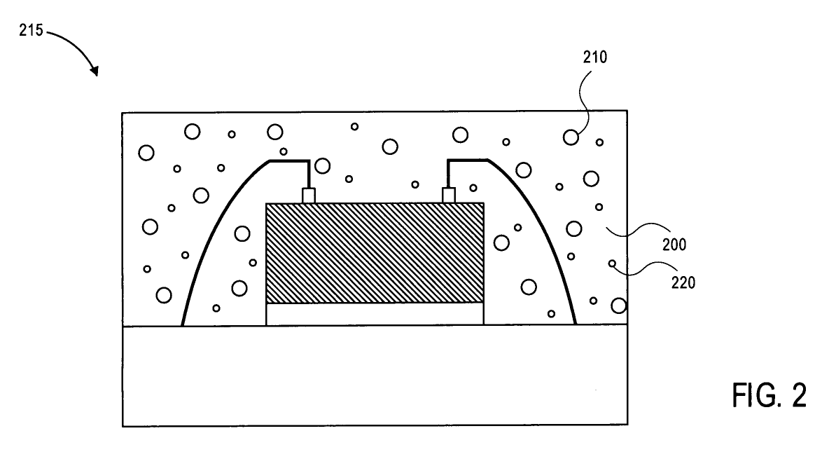

In an embodiment as illustrated in FIG. 2, a composite is used within electronic package 215 as a mold compound. FIG. 2 further illustrates a mold compound composite 200 having a bi-modal size distribution of filler particles. In an embodiment as illustrated in FIG. 2, nanometer size filler particles 220 and micron size filler particles 210 are disposed within mold compound composite 200, which exhibit the filler properties desired.

It is also known in the art that the viscosity of a composite increases exponentially with the addition of fillers. The viscosity of mold compound composite 200 may not increase exponentially when filled with nanometer size filler particles 220 and micron size filler particles 210. In an embodiment, the viscosity of mold compound composite 200 is 20 Pa·s before filled with nanometer and micron size filler particles 220, 210. In an embodiment, the viscosity of mold compound composite 200 remains 20 Pa·s after filled with 60% loading of nanometer and micron size NTE filler particles 220, 210.

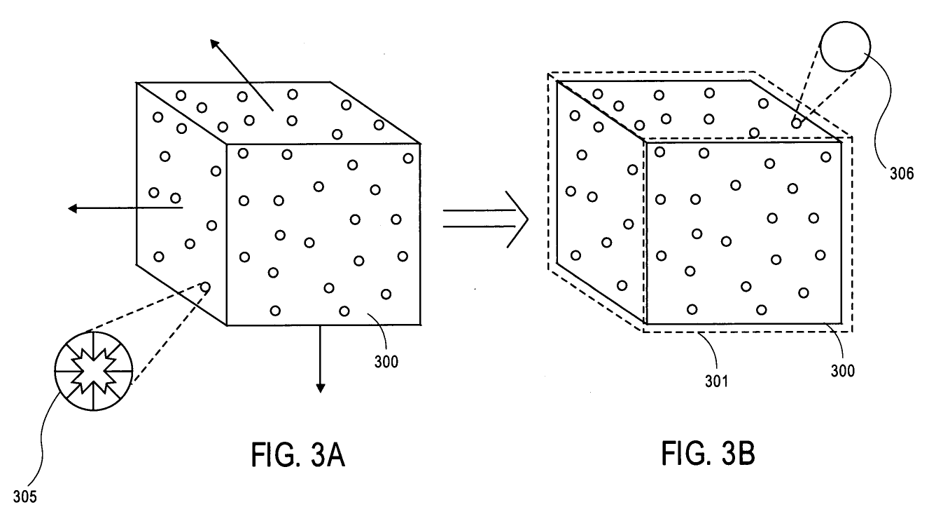

In an embodiment as illustrated in FIG. 3A and 3B, composite 300 has a plurality of NTE filler particles 305. In an embodiment, the size of NTE filler particles 305 is on the order of nanometers. In an embodiment, composite 300 expands upon heating but NTE filler particles 305 contract, which results in an overall lower thermal expansion of composite 300 as illustrated by expanded composite 301 and contracted NTE filler particle 306 of FIG. 3. According to an embodiment when composite 300 includes NTE filler particles 305, the overall expansion of composite 300 is a function of the amount of NTE filler particles 305 applied, up to the theoretical limit.

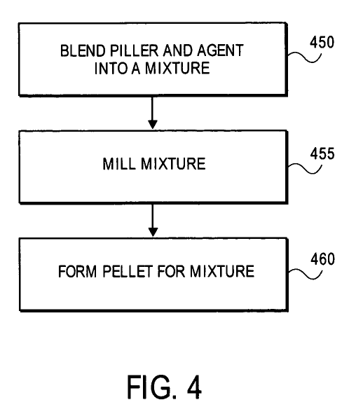

In an embodiment, a composite having a polymer and a bi-modal distribution of NTE filler particles is manufactured according to the process specified in flowchart 400 of FIG. 4. In an embodiment, first negative thermal coefficient of thermal expansion filler particles are blended with additional agents as directed by step 450 of flowchart 400. In an embodiment, 75 g nano and micro size zirconium tungstate filler particles are blended with 16.5 g bishenol F, 13.5 g epoxylated tetramethylbiphenol, 0.3 g carnauba wax, 0.2 g 3, 4 epoxypropyl trimethoxy silane, and 0.15 g triphenyl phosphine. In an embodiment, the mixture is dry blended by a grinding blade. In an embodiment, the mixture is maintained at a temperature below 25° C. during blending. Next, as directed by step 455, the mixture is roll milled at a temperature approximately 110° C. Then, according to step 460, the mixture is ground and pressed into a pellet.

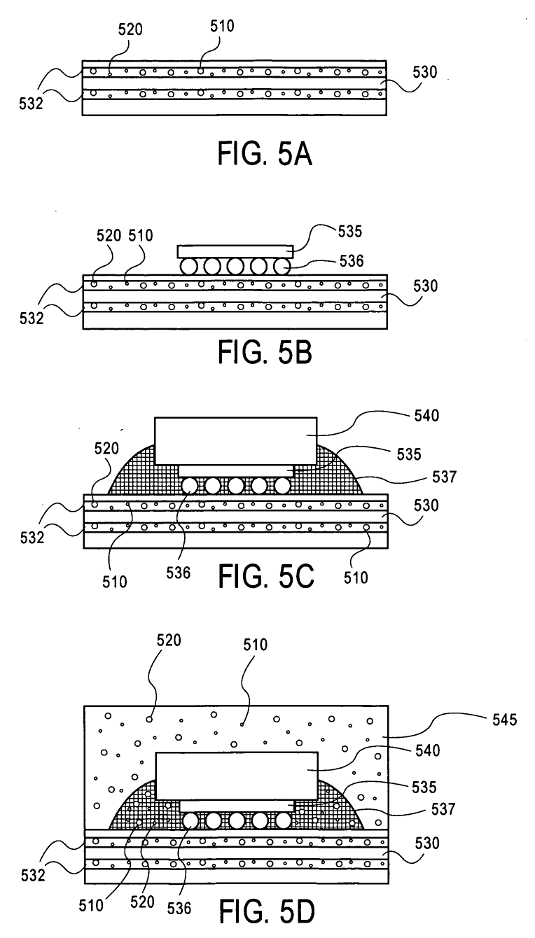

In an embodiment, an electronic package of the present invention may be manufactured by any suitable method known in the art such that the electronic package includes a composite having a polymer and a bi-modal size distribution of filler particles. In yet another embodiment, the electronic package of the present invention is manufactured by a method such that the composite includes a polymer and nanometer size filler particles. In an embodiment, the electronic package may be manufactured by the process illustrated in FIGS. 5A-5D.

To manufacture an electronic package of the present invention according to an embodiment as illustrated in FIGS. 5A-5D, first a substrate 530 is provided as illustrated in FIG. 5A. In an embodiment, substrate 530 functions to connect an electronic package to a motherboard and/or electrically couple the electronic package to other devices. In an embodiment, substrate 530 includes any material suitable to allow attachment with a semiconductor die. Substrate 530 may include an organic or inorganic material. In an embodiment, substrate 530 includes NTE filler particles embedded in buildup layer 532 as illustrated in FIG. 5A. In an embodiment, NTE filler includes a bi-modal size distribution of nanometer and micron size filler particles. In yet another embodiment, NTE filler includes nanometer size filler particles. In an embodiment as illustrated in FIG. 5A, nanometer size filler particles 520 and micron size filler particles 510 are disposed in buildup layer 532.

Next, a semiconductor die 535 is attached to substrate 530 as illustrated in FIG. 5B. In an embodiment, semiconductor die 535 is attached to substrate 530 by any suitable method known in the art. In an embodiment, semiconductor die 530 is attached to substrate 530 by a Control Collapse Chip Connect (C4) process as evident by bumps 536 illustrated in FIG. 5B.

Subsequently, as illustrated in FIG. 5C, an integrated heat spreader 540 is aligned with and adjoined to semiconductor die 535 as illustrated in FIG. 5C by any suitable method known in the art. In an embodiment, integrated heat spreader 540 is adjoined to semiconductor die 535 prior to semiconductor die's 535 attachment to substrate 530. In an embodiment, a thermal interface material 537 is applied between semiconductor die 535, integrated heat spreader 540, and substrate 530 as illustrated in FIG. 5C. In an embodiment, thermal interface material 537 includes a bi-modal size distribution of NTE filler particles, nanometer and micron size filler particles 520 and 510, as illustrated in FIG. 5D.

Then, mold compound composite 545 is applied to the previous stated electronic package components according to an embodiment as illustrated in FIG. 5D. In an embodiment, mold compound composite 545 protects the electronic device mechanically and environmentally from an outside ambient. In an embodiment, mold compound composite 545 includes a bi-modal size distribution of NTE filler particles, nanometer and micron size filler particles 520 and 510, as illustrated.

1. A composite comprising:
a polymer; and
nanometer size filler particles disposed in said polymer.

2. The composite of claim 1, wherein said nanometer size filler particles have a negative coefficient of thermal expansion.

3. The composite of claim 1 further comprises micron size filler particles.

4. The composite of claim 1, wherein the loading of said nanometer size filler particles is less than a 35% weight fraction of said composite.

5. A composite comprising:
a polymer; and
micron size filler particles disposed in said polymer; and
nanometer size filler particles disposed in said polymer; wherein said nanometer size filler particles and said micron size filler particles have a combined loading less than 35% of said composite and wherein said nanometer size filler particles and said micron size filler particles have a negative coefficient of thermal expansion.

6. The composite of claim 5, wherein said nanometer size filler particles and said micron size filler particles are selected from the group consisting of zirconium tungstate, hafnium tungstate, and metal cyanide.

7. The composite of claim 5, wherein the coefficient of thermal expansion of said composite is determined according to a formula: α_{composite}=α_{filler}*V_{filler}+αₘₐₜᵣᵢₓ*Vₘₐₜᵣᵢₓ+βᵢ(3V_{filler}/r); wherein r is the average particle radius, βᵢ is the product of αᵢ (CTE of the interface polymer) and tᵢ (thickness of the interface layer), and V is the volume of the filler.

8. A composite comprising:
a polymer; and
hafnium tungstate filler particles disposed in said polymer.

9. The composite of claim 8, wherein said polymer is selected from the group consisting of an underfill, die-attach, mold compound, encapsulant, and sealant.

10. The composite of claim 8, wherein the size of said hafnium tungstate filler particles are on the order of nanometers.

11. A composite comprising:
a polymer; and
metal cyanide filler particles disposed in said polymer.

12. The composite of claim 11, wherein said metal cyanide filler particles further comprise Prussia blue crystalline structures.

13. A method of forming an electronic package comprising:
providing a substrate;
attaching a semiconductor die to said substrate;
applying a mold compound on said substrate and on said semiconductor die, wherein said mold compound comprises nanometer size filler particles.

14. The method of claim 13, wherein said mold compound comprises micron size filler particles.

15. The method of claim 13, wherein said nanometer size filler particles are selected from the group consisting of zirconium, tungstate, hafnium tungstate and metal cyanide.

16. A method of forming an electronic package comprising:
providing a substrate;
attaching a semiconductor die to said substrate;
applying an underfill to said substrate wherein said underfill is positioned substantially between said semiconductor die and said substrate, and wherein said underfill comprises nanometer size filler particles;
applying a mold compound on said substrate and said semiconductor die.

17. The method of claim 16, wherein said mold compound comprises nanometer size filler particles.

18. The method of claim 16, wherein said mold compound comprises micron size filler particles.

19. A method of forming a mold compound comprising:
blending epoxylated tetramethylbiphenol, bishenol, zirconium tungstate, carnauba wax, epoxypropyl trimethoxy silence, and triphenyl phosphine into a mixture;
milling said mixture;
pressing said mixture into a pellet.

20. The method of claim 19, wherein said zirconium tungstate comprises nanometer size filler particles.

21. The method of claim of 19, wherein said zirconium tungstate comprises micron size filler particles.
